(19) United States
(12) Patent Application Publication
(10) Pub. No.: US 2017/0294606 A1
(43) Pub. Date: Oct. 12, 2017

(54) Iridium complex, method for manufacturing same, and organic light-emitting devices using same

(71) Applicant: AAC Technologies Pte, Ltd., Singapore City (SG)

(72) Inventors: Youxuan Zheng, Nanjing (CN); Yi Pan, Nanjing (CN); Yi Wang, Nanjing (CN); Jinglin Zuo, Nanjing (CN); Qiulei Xu, Nanjing (CN)

(21) Appl. No.: 15/480,544

(22) Filed: Apr. 6, 2017

(30) Foreign Application Priority Data
Apr. 7, 2016 (CN) 201610213570.8

(51) Int. Cl. H01L 51/00; C09K 11/06; C07F 15/00

(52) U.S. Cl. CPC H01L 51/0085; C07F 15/0033; C09K 11/06; H01L 51/0097; H01L 51/5206

(57) ABSTRACT

An iridium complex is disclosed. The main auxiliary ligand of the iridium complex molecule is selected from 2-(4,6-bistrifluoromethylpyridine) pyridine, 2-(4,6-bistrifluoromethylpyridine) DMCP, 2-(4,6-bistrifluoromethylpyridine) tetramethypyrazine and 2-(4,6-bistrifluoromethylpyridine) triazine derivatives. Such new iridium complex in the invention not only owns the high luminous efficiency, stable chemical property, easy sublimation purification and other advantages, but also has good device performance. By embellishing the molecular structure of ligand, it could adjust the light intensity and efficiency of complexes within the scope of green light wavelength, which provides the convenience for the design and production of Organic Light Emitting Device and lighting source.

### FIELD OF THE PRESENT DISCLOSURE

The present invention relates to novel organic compounds that may be advantageously used in organic light emitting devices. More particularly, the invention relates to iridium complexes and their use in OLEDs.

### DESCRIPTION OF RELATED ART

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE, coordinates, which are well known to the art.

In recent years, many researches indicate that the iridium complex is regarded as the most ideal selection of OLEDs phosphor materials among many heavy metal element complexes. After forming +3 cation, the Iridium atoms with 5d⁷6s² outer electron structure owns the 5d⁶ electron configuration and the stable hexa-coordinate octahedral structure, which lets the materials own higher chemical stability and heat stability. Meanwhile, Ir(III) owns larger spin-orbit coupling constants (ξ=3909 cm-1), which is conductive to improving the quantum yield of complexes and reducing the luminescence Lifetime, thus improving the whole performance of illuminator.

As the phosphor materials, in general, the iridium complex easily causes in the microsecond phosphorescence quenching between triplet-triplet of iridium complex and triplet-polaron. In addition, in the current common materials, the hole mobility of hole-transport material is far higher than the electronic mobility of electron transport material, and the common host materials give priority to the hole transport, which would cause that many redundant electron holes gather on the luminescent layer and electron transfer layer surface. All these factors would result the efficiency reduction and the severe efficiency roll-off. It's indicated in the research that: in case of owning higher electronic transmission ability, the iridium complex could effectively increase the transmission and distribution of electron in luminescent layer, expand the area of electron-hole and balance the quantity of electron-hole pairs, which greatly improves the efficiency of device and reduces the efficiency roll-off.

Thereof, it is necessary to disclose and provide improved Iridium complex to overcome the above-mentioned disadvantages.

### BRIEF DESCRIPTION OF THE DRAWINGS

FIG. 1 is an electroluminescent spectra of an iridium complex GIr9-001 used in an organic light-emitting device;

FIG. 2 is an photoelectric property of the iridium complex GIr9-001 used in the organic light-emitting device; and

FIG. 3 is an photoelectric property that the iridium complex GIr9-001 used in the organic light-emitting device.

### DETAILED DESCRIPTION OF THE EXEMPLARY EMBODIMENT

The present disclosure will hereinafter be described in detail with reference to an exemplary embodiment. To make the technical problems to be solved, technical solutions and beneficial effects of the present disclosure more apparent, the present disclosure is described in further detail together with the figure and the embodiment. It should be understood the specific embodiment described hereby is only to explain the disclosure, not intended to limit the disclosure.

In the synthetic process of an iridium complex in the invention, the Iridium trichloride, 4,6-difluoromethyl and trifluoromethyl pyridine-3 boracic acid, 4,6-difluoromethyl and trifluoromethyl pyridine-4-boracic acid, 2-Bromide pyridine derivatives, 2-Bromine pyrimidine derivatives, 2-Bromine pyrazine derivatives and 2-Bromine triazine derivatives with the similar synthesis methods. Iridium complex contains two main ligands and one 2-(5-(3-pyridyl-1,3,4-oxadiazole-2) phenol auxiliary ligand, in which the main ligands at question are each of 2-(4,6-bistrifluoromethylpyridyl) pyridine, 2-(4,6-bistrifluoromethylpyridine) pyrimidine, 2-(4,6-bistrifluoromethylpyridine) tetramethypyrazine and 2-(4,6-dibtrifluoromethylpyridine) triazine derivatives. As mix iridium dimerization bridging complex containing two main ligands and the 2-(5-(3-pyridyl-1,3,4-oxadiazole-2-)phenol auxiliary ligand and sodium carbonate; 2-ethoxyethanol solution is added for the heating reaction at 120-140° C. for 12-48 h, then cool down to the room temperature, remove the solvent by decompression and distillation, then extract and concentrate with dichloromethane, finally gain the crude product of complexes by column chromatography isolation, and gain iridium complex through sublimation. Wherein, the iridium dimerization bridging complex at question contains each of 2-(4,6-bistrifluoromethylpyridyl) pyridine, 2-(4,6-bistrifluoromethylpyridyl) pyrimidine, 2-(4,6-bistrifluoromethylpyridyl) tetramethypyrazine and 2-(4,6-bistrifluoromethylpyridine) triazine derivatives, and the molar ratio of iridium dimerization bridging complex, auxiliary ligand and sodium carbonate is 1:2:5.

The ligand which is neutralized with iridium C atom to form a pyridine derivatives are:

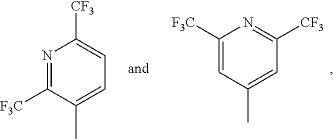

the connection locations between the pyridine, pyrimidine and pyrazine in the mentioned pyridine derivatives and ligand and the triazine derivatives are different. Arbitrarily bit of mentioned pyridine, pyrazine, pyrimidine and triazine derivatives are replaced by halogen or alkyl group. The quantity of substituent group on the mentioned pyridyl, the pyrimidine and pyrazinyl and the triazinyl are 0-4, 0-3 and 0-2 respectively.

In case of optimization, the mentioned halogen is F, and the mentioned alkyl group is any one in trifluoromethyl, methyl.

The preferable 4,6-bistrifluoromethylpyridine in the main complex has different attachment positions with pyridine, pyrimidine, pyrazine, and triazine derivatives, taken from the 3 and 4 position; The mentioned pyridine, pyrimidine, pyrazine and triazine derivatives are selected from

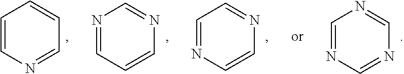

This iridium complex corresponds to the different main ligands and has the following different structures:

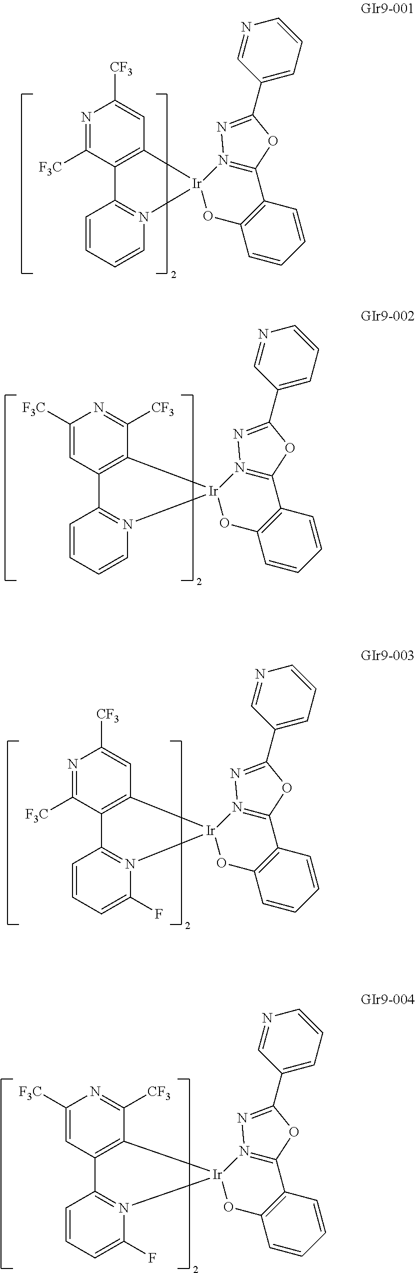

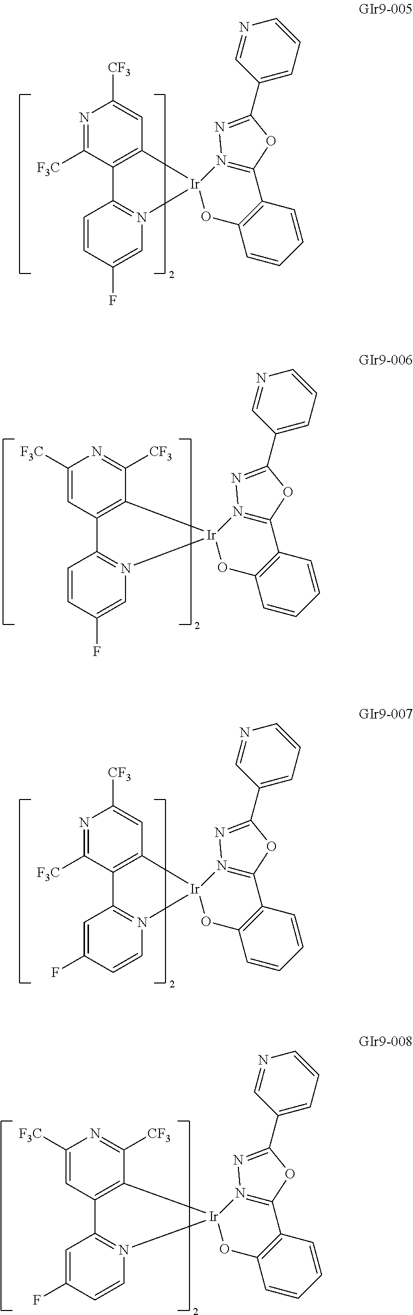

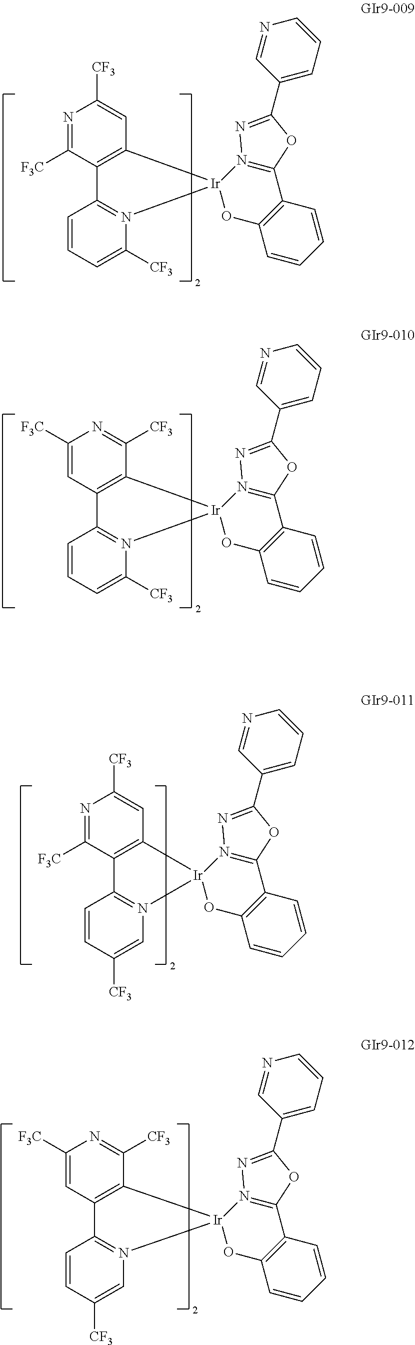

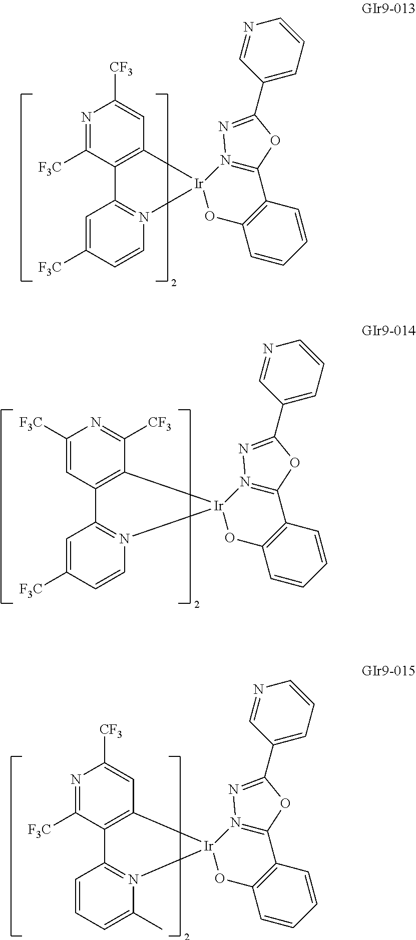

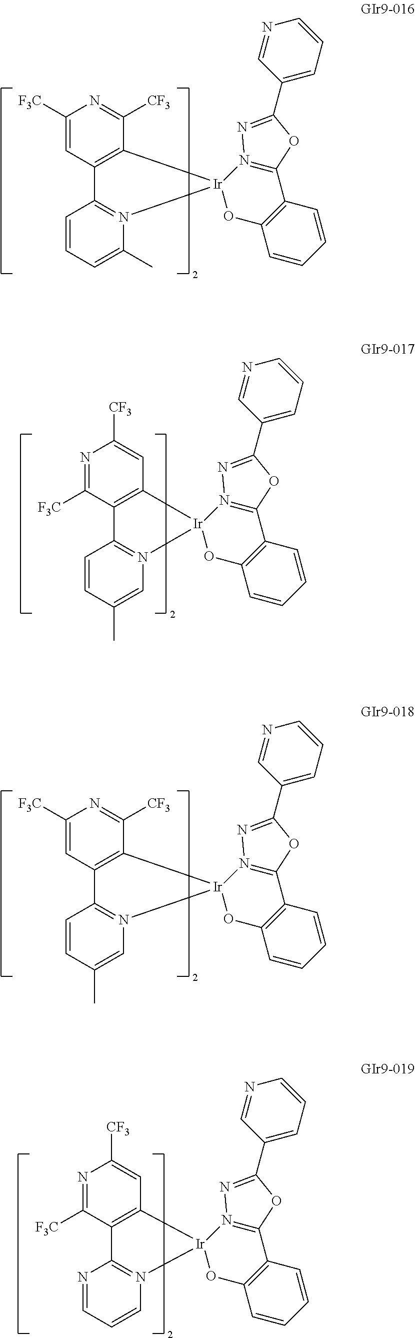

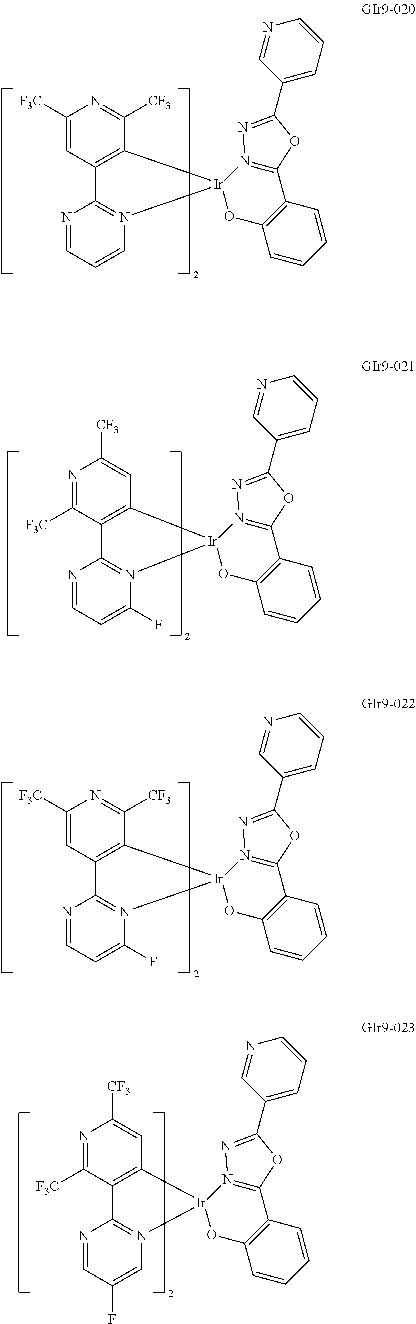

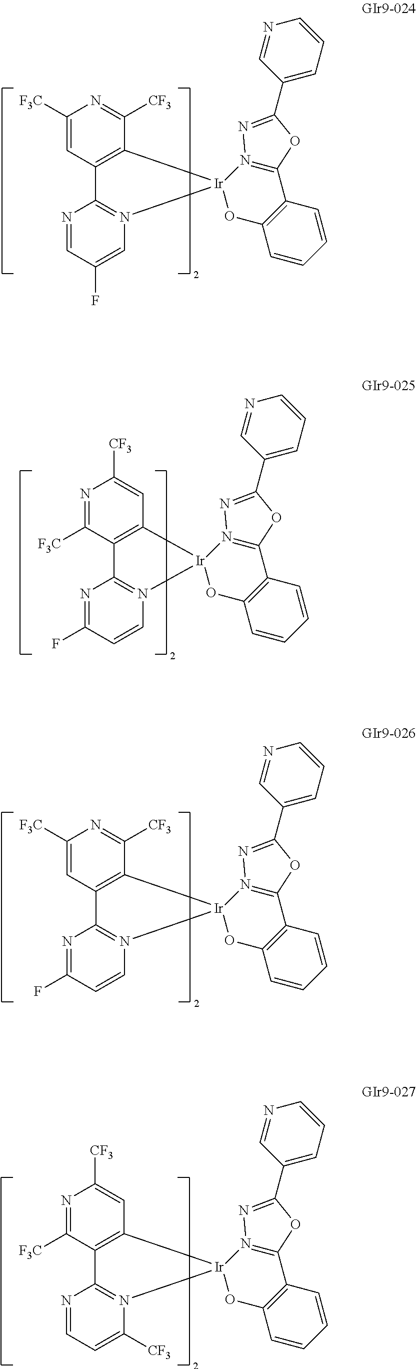

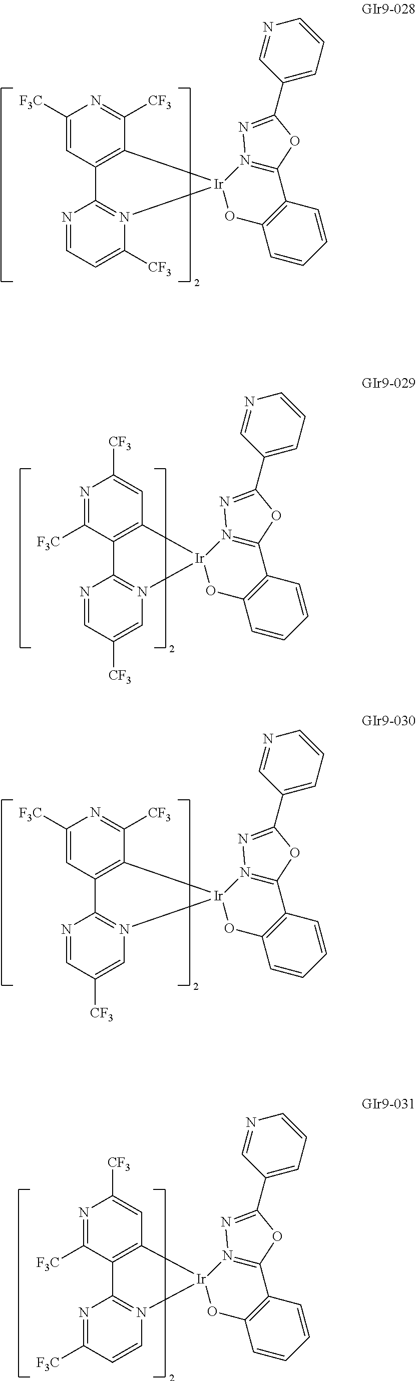

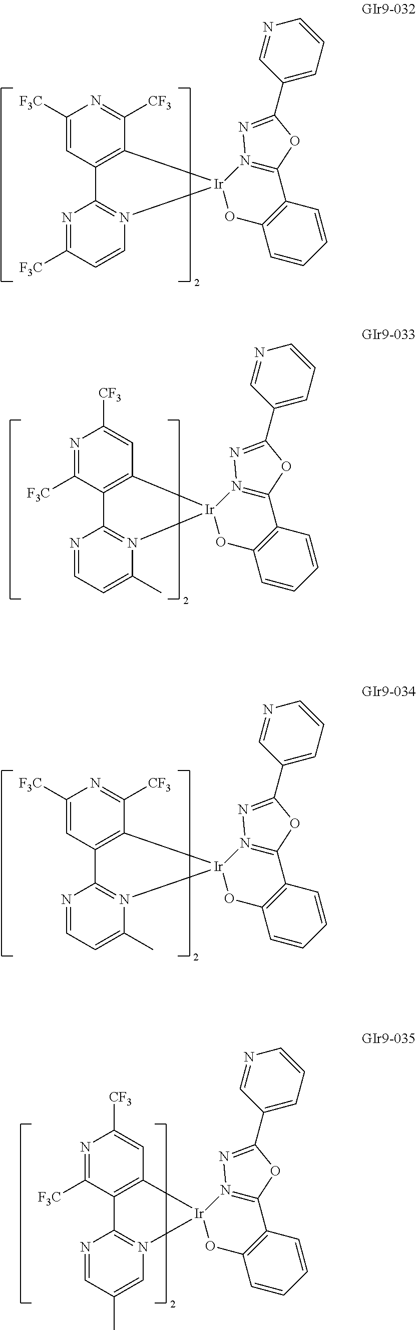

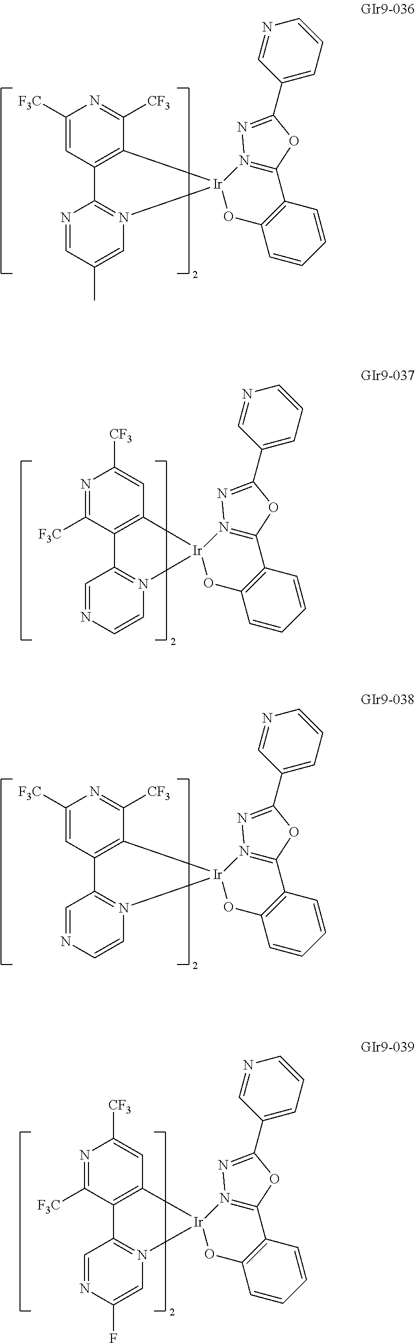

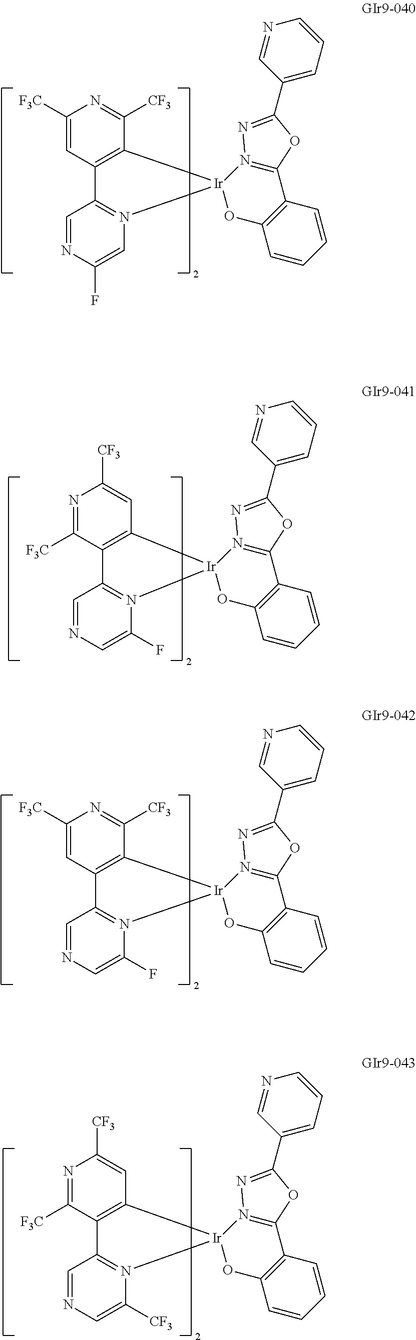

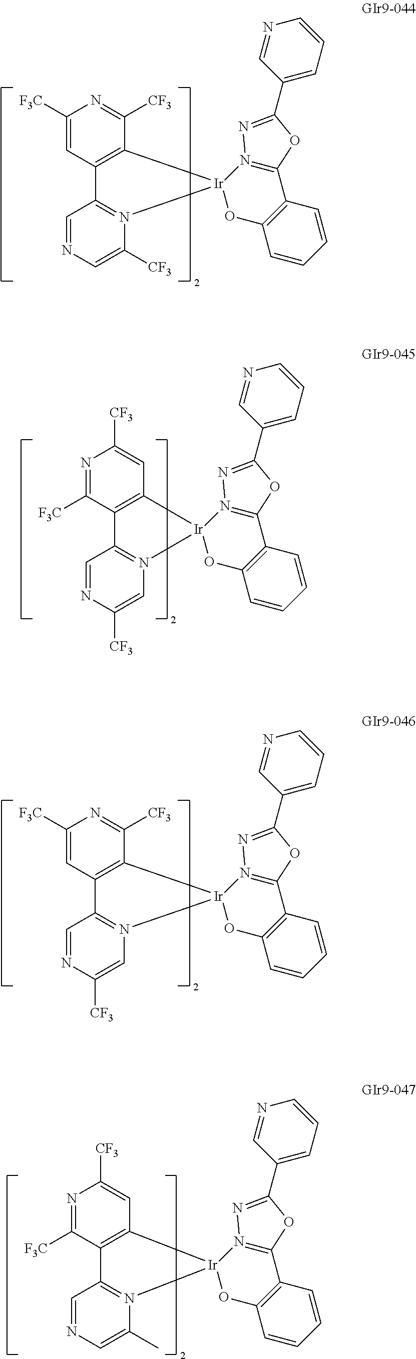

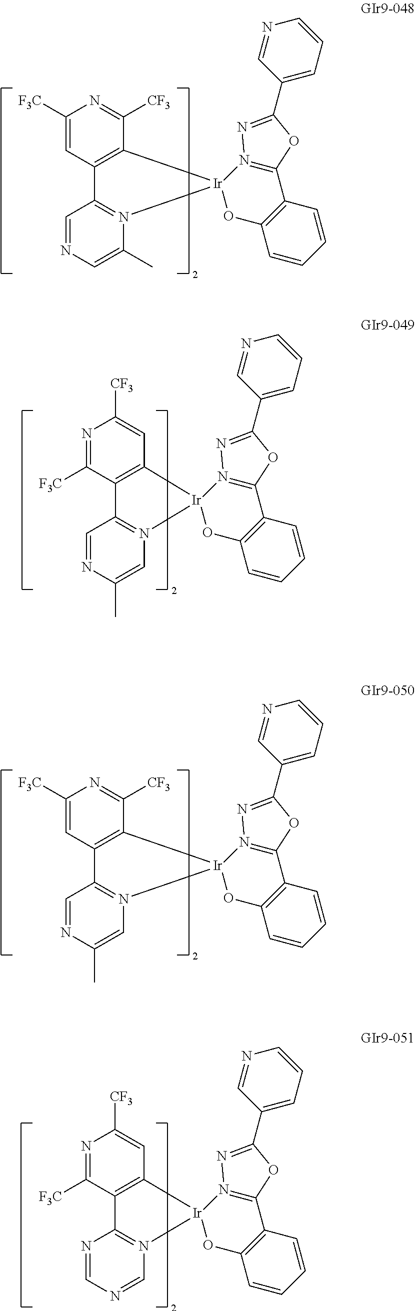

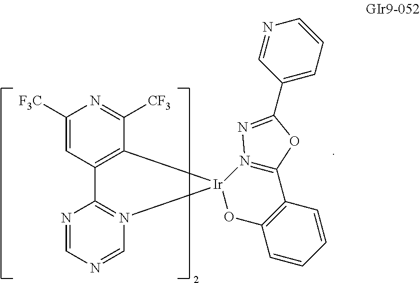

Based on one following example, the complexes GIr9-001 is used to specially describe the invention content, which would be conductive to further undertaking the invention, but isn't limited to the invention content.

Manufacturing method of complexes GIr9-001:

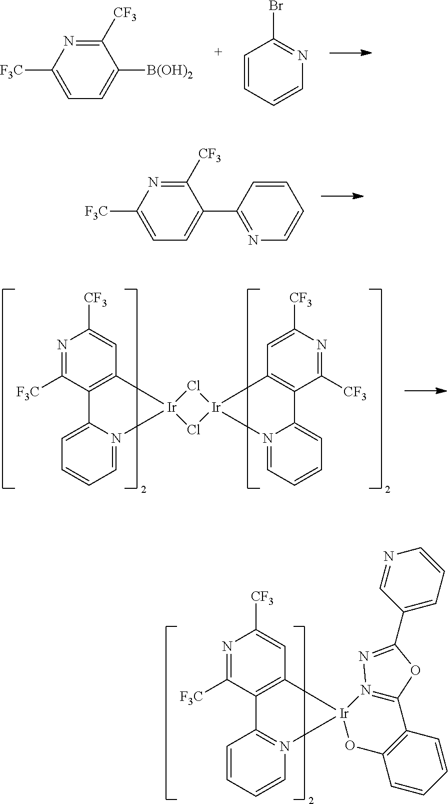

2-Bromine pyridine (26.39 mmol), 4,6-difluoromethyl and trifluoromethyl pyridine-3-boracic acid (31.66 mmol), (beta-4)-platinu (0.79 mmol) and sodium carbonate (60.00 mmol are dissolved in 100 mL butylene oxide with 65 oC reaction for 24 hours, then cool down and add water and dichloromethane. Finally, the main ligand (productivity is 52.24%) is gained from the organic horizon concentrating column by chromatography. Dissolve main ligand (13.08 mmol) and Iridium trichloride (6.23 mmol) in 15 mL 2-ethoxyethanol with mixture 130° C. reaction for 12 h, then add the 2-(5-(3-phenyl-1,3,4-oxadiazole-2-)phenol (12.46 mmol) and sodium carbonate (31.15 mmol), and continue the 130° C. reaction for 24 h. After the system cools down, add water and dichloromethane, then gain yellow solid GIr9-001 from the organic horizon concentrating column by chromatography with the productivity of 44%.

Its nuclear magnetism and mass spectral characterization data: ¹H NMR (500 MHz, CDCl3) δ 9.09 (d, J=5.6 Hz, 2H), 8.29 (d, J=8.4 Hz, 2H), 7.66 (t, J=8.0 Hz, 2H), 7.16 (t, J=7.4 Hz, 2H), 7.32 (t, J=6.6 Hz, 1H), 7.18-7.14 (m, 3H), 6.83 (t, J=6.5 Hz, 2H), 6.59 (d, J=8.6 Hz, 1H), 6.49 (t, J=7.4 Hz, 1H), 6.42 (s, 1H), 6.28 (s, 1H). ESI-MS: m/z 1013.10 [M]+, found: 1012.78 [M]+.

A serial of iridium complexes with green-ray were designed in this invention with each of 2-(4,6-bistrifluoromethylpyridyl) pyridine, 2-(4,6-bistrifluoromethylpyridine) pyrimidine, 2-(4,6-bistrifluoromethylpyridine) tetramethypyrazine and 2-(4,6-dibtrifluoromethylpyridine) triazine derivatives as main ligand and 2-(5-(3-pyridyl-1,3,4-oxadiazol-2) as auxiliary ligand. It reaches the purpose for control of complexes shining and electronic mobility by designing ligand or complexes structure and embellishing the simple chemical substituent group on ligand.

All mentioned Nitrogen heterocycles are the group with stronger electronic transmission, which is conductive to balancing the injection and transmission of current carrier.

The mentioned iridium complex owns higher luminous efficiency and electronic mobility. After the optimization verification, it has simple is preparation method with higher productivity.

Preparation of Organic Light-Emitting Device

Based on the following example that GIr9-001 (iridium complex) is used to prepare the organic light-emitting device, the preparation of the organic light-emitting device in the invention is described. The structure of OLEDs device includes: Substrate, anode, hole transport layer, organic light emitting layer and electron transfer layer/cathode.

The substrate for the manufacturing the device in the invention is glass, and its anode materials are indium tin oxide (ITO); Hole transport layer uses the 4,4′-Cyclohexyl 2 [N,N (4-methyl phenyl) aniline (TAPC), the material in electronic transport layer uses 3,3′-(5′-(3-(pyridine-3-buty) phenyl)-[1,1′: The cathode uses LiF/Al, their thicknesses are 1 nm and 100 nm respectively, and their evaporation rates are 0.01 nm/s and 0.2 nm/s respectively. Organic light emitting layer is the doping structure, main body material is 1,3-bi (9H-carbazole-9-buty) benzene (mCP), and the luminescent materials selected is GIr9-001. The thickness of luminescent layer is 40 nm, the evaporation rate is 0.05 nm/s, and the GIr9-001 mass fraction is 8%.

The structure of several materials used in the invention is as follows:

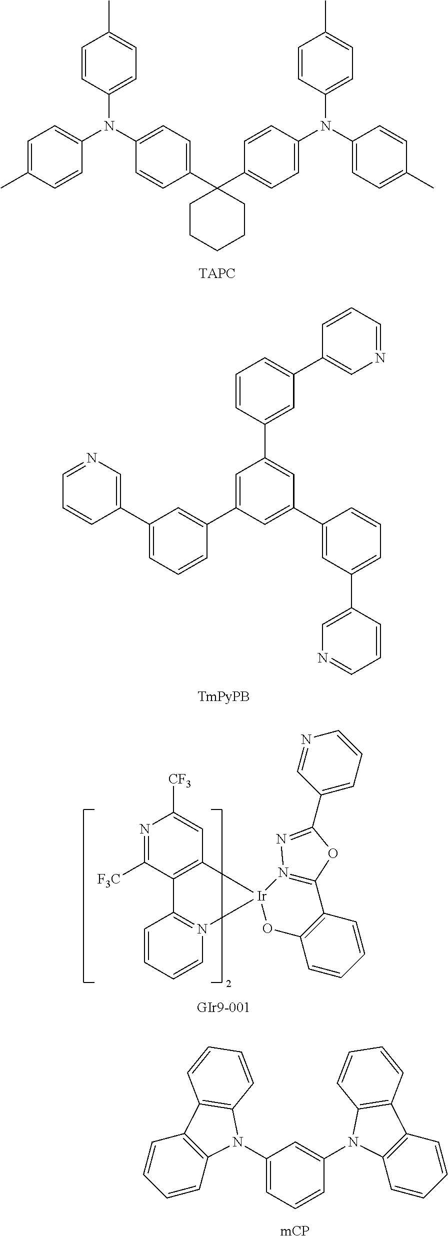

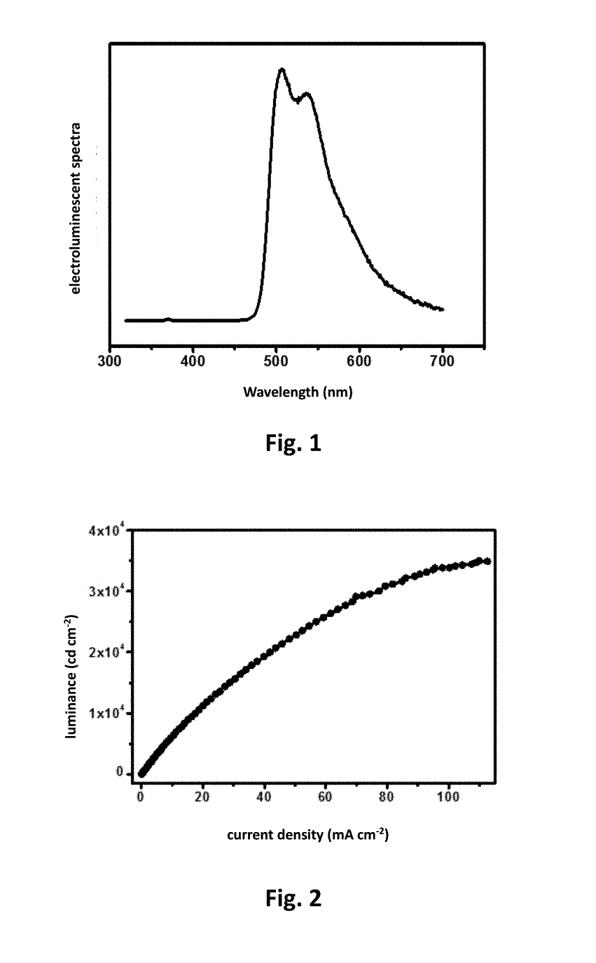

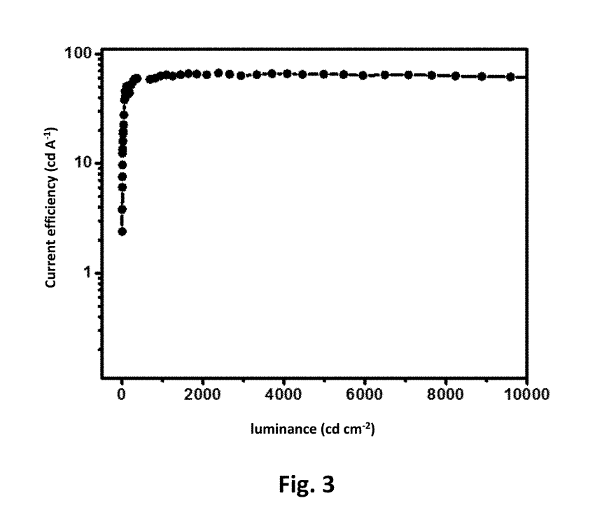

The green-ray complexes are selected in the invention to prepare the organic light-emitting device. Please refer to FIGS. 1-3 together, in which, FIG. 1 shows the electroluminescent spectra that the iridium complex in the invention is used in organic light-emitting device, FIGS. 2-3 show photoelectric property that the iridium complex in the invention is used in organic light-emitting device. As shown in FIGS. 2 and 3, the maximum power efficiency and current efficiency of the organic electroluminescent device at question are 35.48 lm/W and 72.63 cd/A, respectively, and the maximum luminance is 36677 cd/m2. By researching the photophysical property, it's indicated that such phosphorescence iridium complex with Nitrogen Heterocycles owns higher device efficiency, and owns the practical application value in the display, lighting and other fields.

The phosphor materials in the invention could be applied in emission layer of phosphorescence OLEDs as the luminescence center. And the invention could control the emitting color and efficiency of complexes by designing ligand or complexes structure and embellishing the chemical substituent group on mentioned ligand.

It is to be understood, however, that even though numerous characteristics and advantages of the present exemplary embodiment have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

1. An iridium complex comprising two main ligands and a 2-(5-(3-pyridyl-1,3,4-oxadiazole-2) phenol auxiliary ligand, the main ligands being selected from 2-(4,6-bistrifluoromethylpyridyl) pyridine, 2-(4,6-bistrifluoromethylpyridine) pyrimidine, 2-(4,6-bistrifluoromethylpyridine) tetramethypyrazine and 2-(4,6-dibtrifluoromethylpyridine) triazine derivatives, wherein the ligand which is neutralized with iridium C atom to form a pyridine derivatives are: 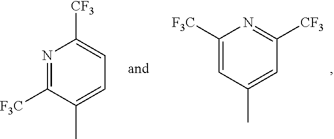
the connection locations between the pyridine, pyrimidine and pyrazine derivatives in the mentioned pyridine derivatives and ligand and the triazine derivatives are different; arbitrarily bit of mentioned pyridine, pyrazine, pyrimidine and triazine derivatives are replaced by halogen or alkyl group;
the quantity of substituent group on the mentioned pyridyl, the pyrimidine and pyrazinyl and the triazinyl are 0-4, 0-3 and 0-2 respectively.

2. The iridium complex as described in claim 1, wherein the mentioned halogen is F, and the mentioned alkyl group is any one in trifluoromethyl, methyl.

3. The iridium complex as described in claim 2, wherein the 4,6-bistrifluoromethylpyridine in the main ligand has different attachment positions with pyridine, pyrimidine, pyrazine, and triazine derivatives in different main ligands, taken from the 3 and 4 positions; the mentioned pyridine, pyrimidine, pyrazine and triazine derivatives are selected from

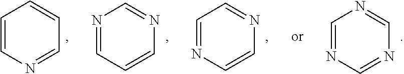

4. Based on the iridium complex as described in claim 3, wherein the mentioned iridium complex owns one of the following structures:

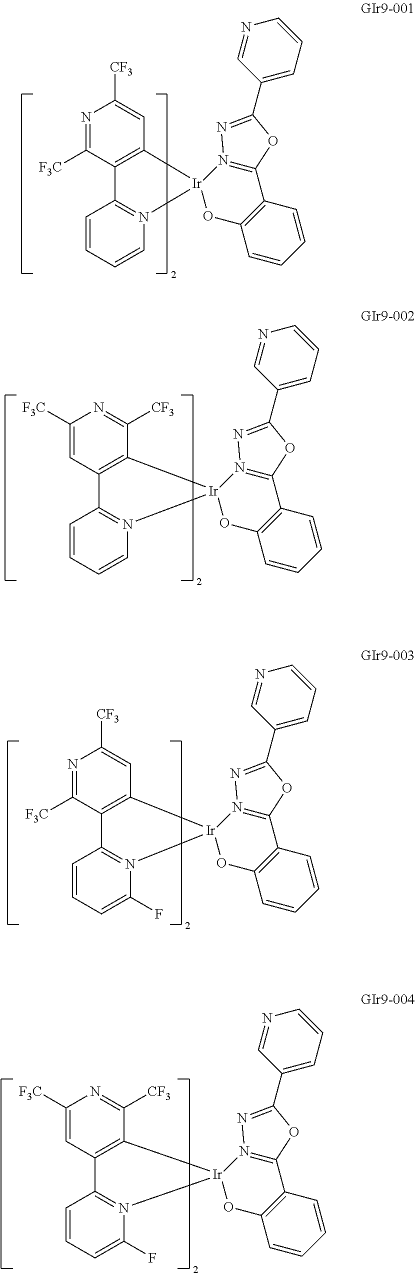

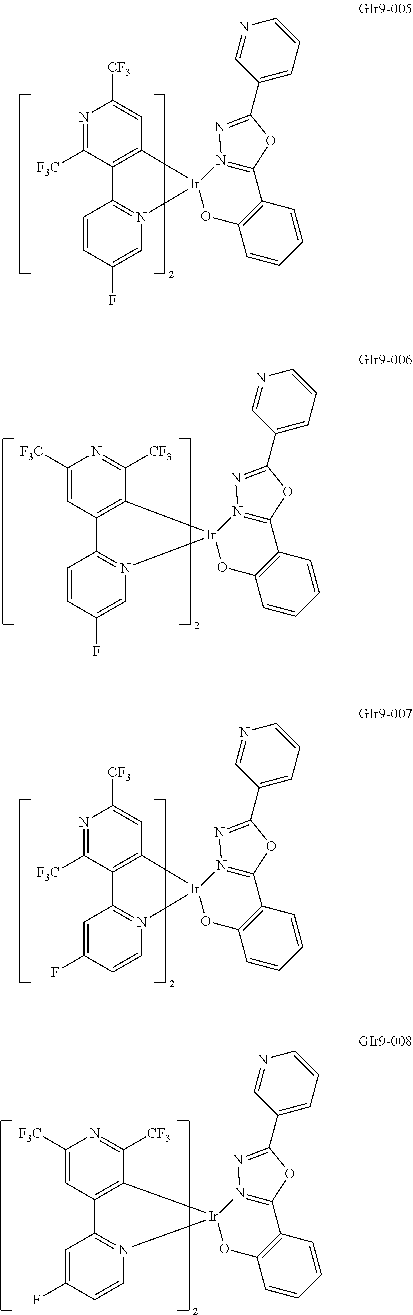

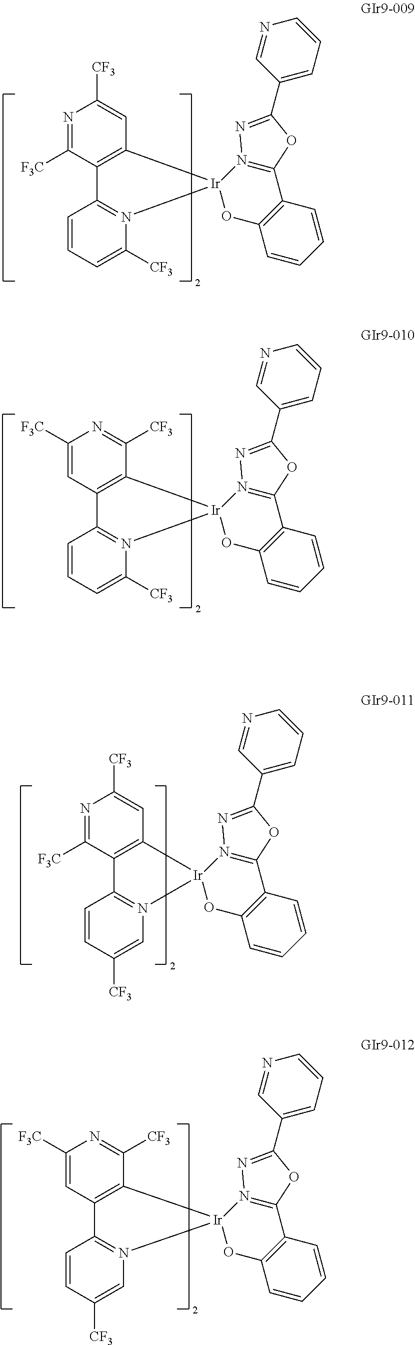

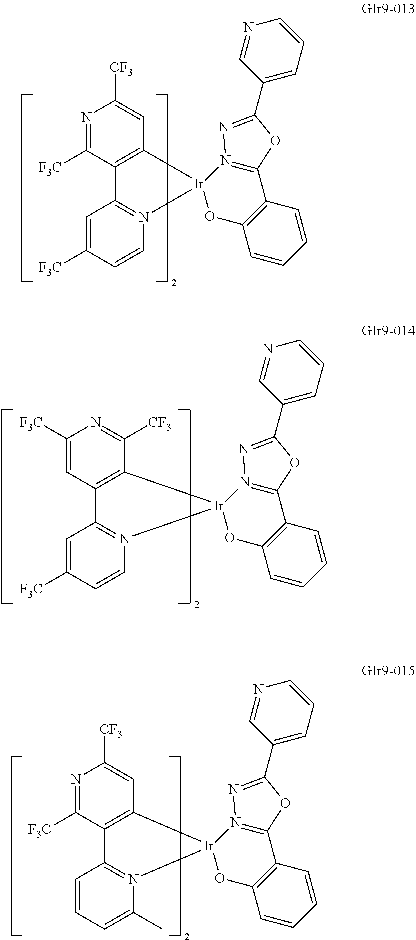

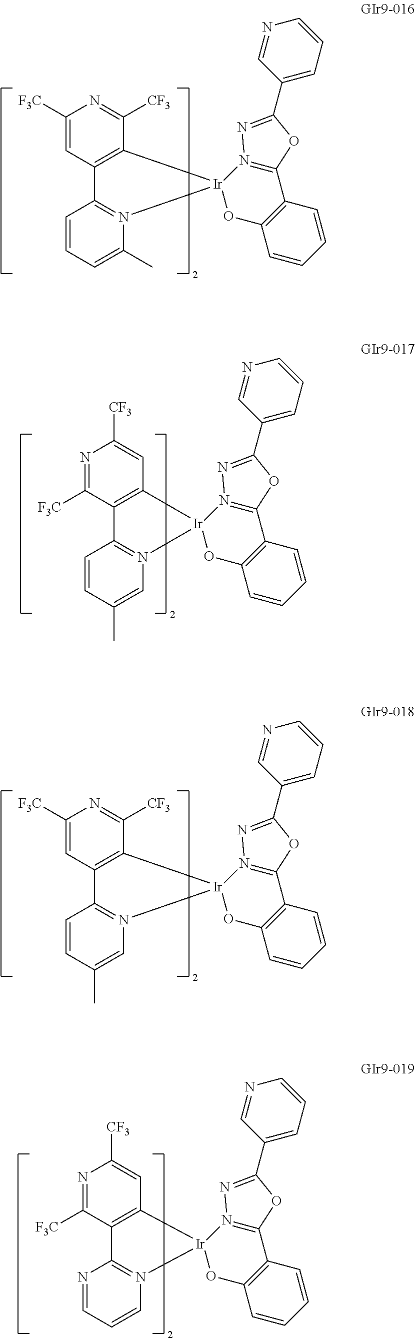

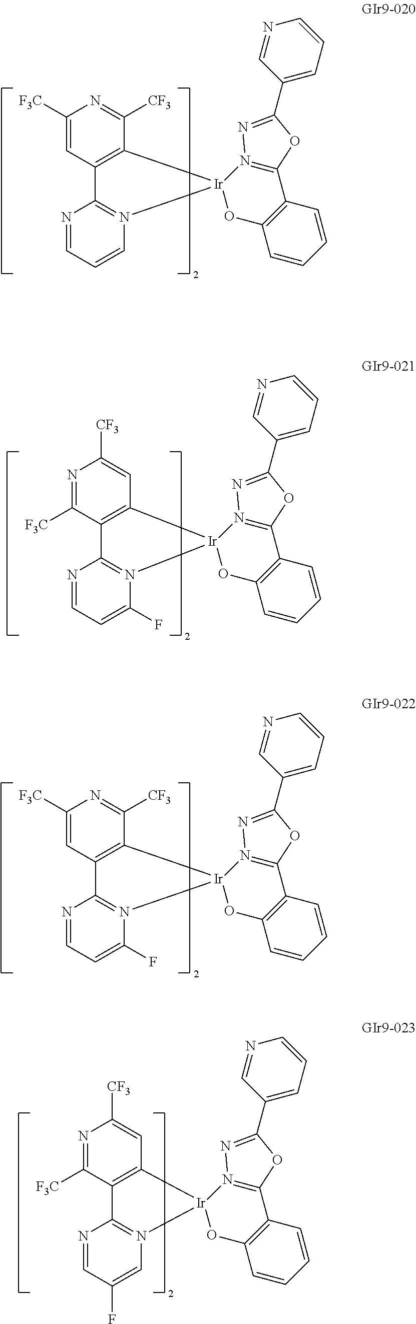

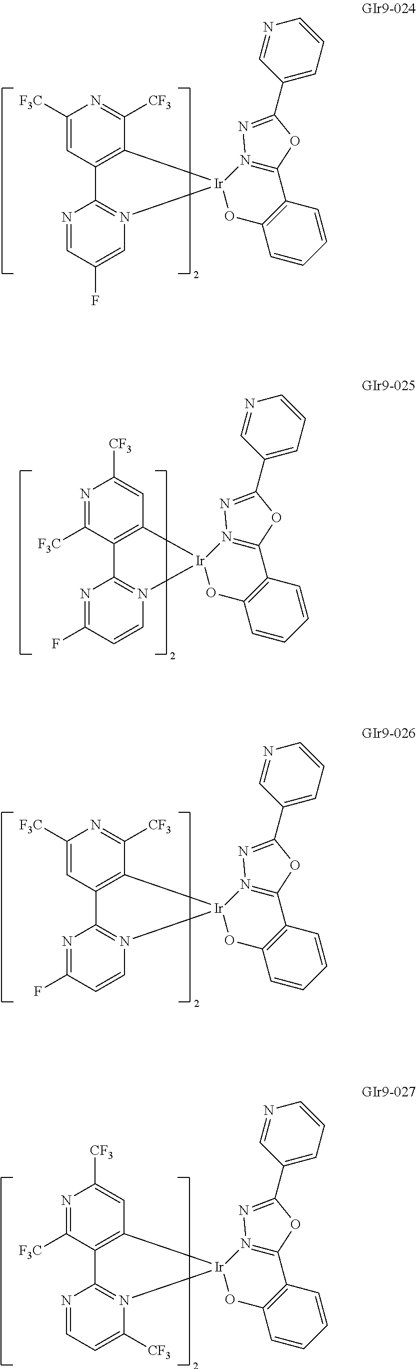

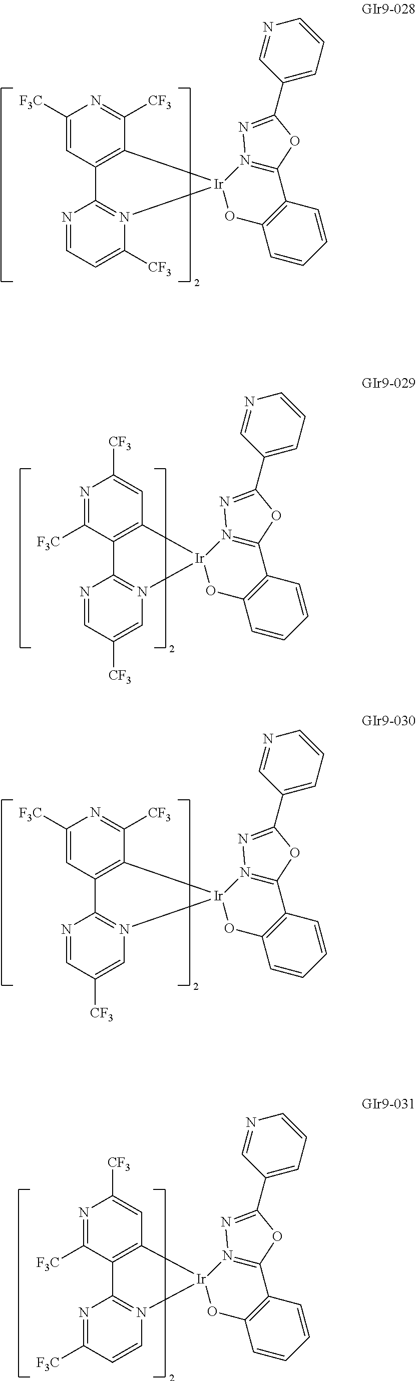

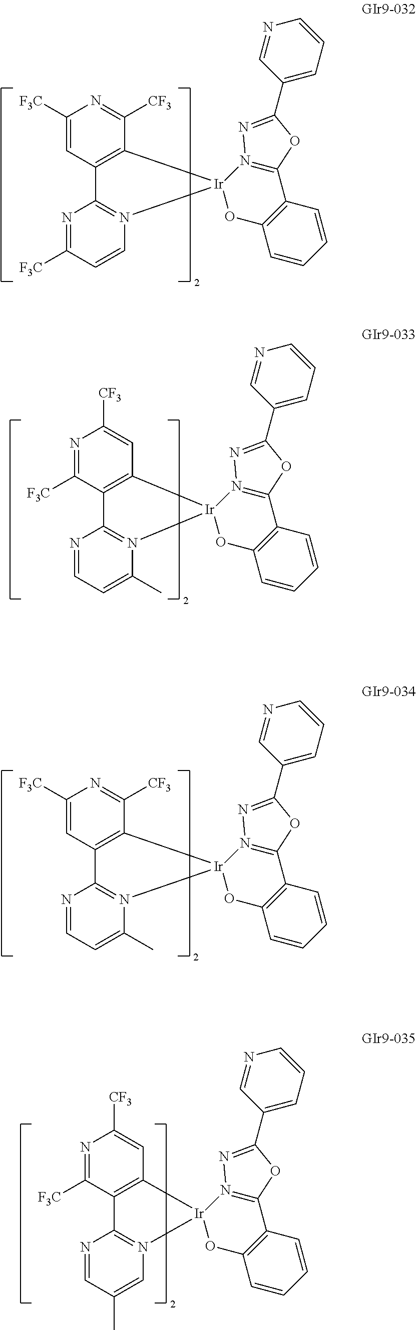

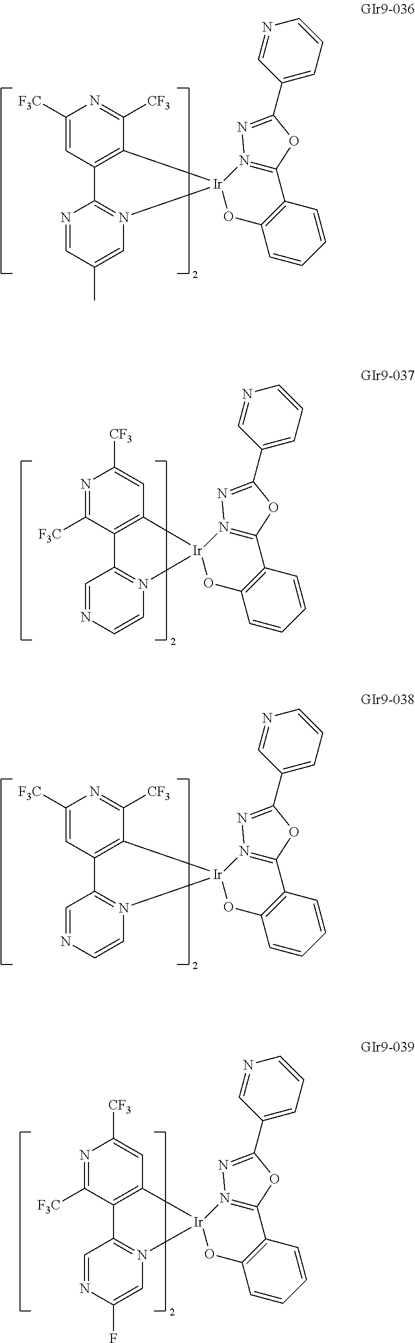

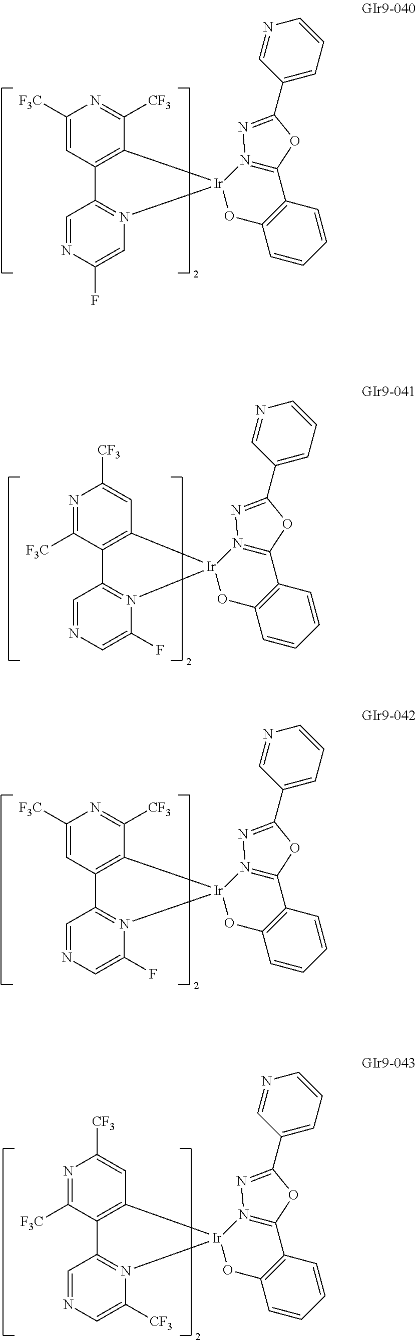

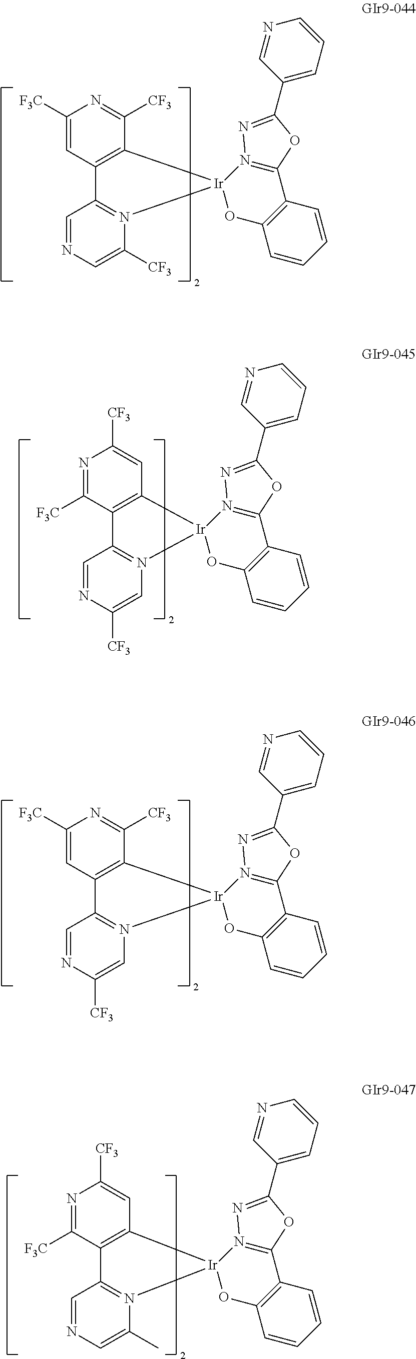

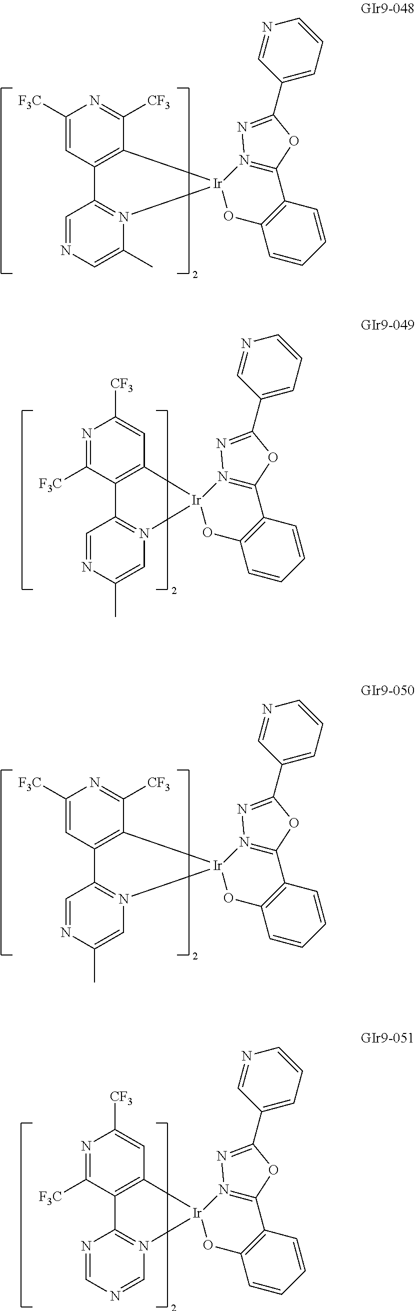

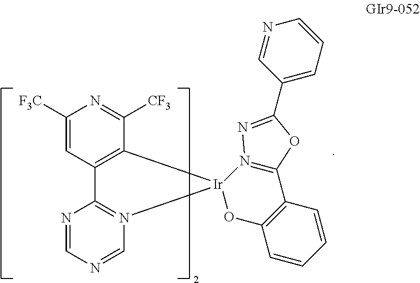

5. A manufacturing method for an iridium complex, comprising the steps of:
mixing two iridium dimerization bridging complexes of main ligand and 2-(5-(3-phenyl-1,3,4-oxadiazol-2-)phenol auxiliary ligands and sodium carbonate, the main ligand being selected from 2-(4,6-bistrifluoromethylpyridyl) pyridine, 2-(4,6-bistrifluoromethylpyridyl) pyrimidine, 2-(4,6-bistrifluoromethylpyridyl) tetramethypyrazine and 2-(4,6-bistrifluoromethylpyridine) triazine derivatives;
adding 2-ethoxyethanol solution for the heating reaction at 120-140° C. for 12-48 h;
cooling down to a room temperature;
removing the solvent by decompression and distillation;
extracting and concentrating with dichloromethane;
gaining the crude product of complexes by column chromatography isolation, and gaining pure iridium complex through sublimation.

6. The manufacturing method for an iridium complex as described in claim 5, wherein the molar ratio of iridium dimerization bridging complex and 2-(5-(3-phenyl-1,3,4-oxadiazol-2-)phenol and sodium carbonate is 1:2:5.

7. An organic light-emitting diode device applying the iridium complex as described in claim 1 comprising a substrate, an anode, a hole transport layer, an organic light-emitting layer, an electron transport layer and a cathode; wherein the substrate is glass, the anode is indium tin oxide, the hole layer is made of TAPC material, the electron transport layer is made of TmPyPB material, the organic light-emitting layer comprises body material and luminous material, the body material is 1,3-bis(9H-carbazol-9-yl)benzene/mCP, the luminous material comprises the iridium complex.
